(19) United States
(12) Patent Application Publication
(10) Pub. No.: US 2012/0062268 A1
(43) Pub. Date: Mar. 15, 2012

(54) METHOD AND DEVICE FOR MEASURING THE RELIABILITY OF AN INTEGRATED CIRCUIT

(75) Inventors: Remy Chevallier, Crolles (FR); Vincent Huard, Le Versoud (FR); Neeraj Kapoor, Delhi (IN); Xavier Federspiel, Equevilley (FR)

(73) Assignees: STMICROELECTRONICS PVT LTD., Greater Noida (IN); STMICROELECTRONICS (CROLLES 2) SAS, Crolles Cedex (FR)

(21) Appl. No.: 13/230,981

(22) Filed: Sep. 13, 2011

(30) Foreign Application Priority Data
Sep. 14, 2010 (FR) 1057334

(51) Int. Cl. G01R 31/26

(52) U.S. Cl. 324/762.01

(57) ABSTRACT

Electromigration may cause a fault to appear in an integrated circuit located on a semiconductor chip. To detect such a fault, at least one resistive test structure is provided separated from the integrated circuit and located on at least one metallization level of the integrated circuit. During operation of the integrated circuit, the resistive test structure is sensed. Detection of a voltage difference between two points of the resistive test structure is indicative of a fault.

### PRIORITY CLAIM

This application claims priority from French Application for Patent No. 1057334 filed Sep. 14, 2010, the disclosure of which is hereby incorporated by reference.

### TECHNICAL FIELD

The invention relates to integrated circuits and more particularly to the detection of the risks of faults appearing, as a result of electromigration, within an integrated circuit located on a semiconductor chip.

### BACKGROUND

Electromigration is an effect that may occur in the metallic lines of integrated circuits and in which metal atoms move as a result of the application of a very high current density. These movements are capable of causing faults such as line severing.

The decrease in the dimensions of the metallic lines of integrated circuits has the drawback of increasing the risk that faults resulting from the electromigration effect will appear. Thus, the most advanced technologies require both fabrication methods that are able to reduce the appearance of faults, and test methods that detect the appearance of faults.

Currently used test methods allow faults to be detected by means of dedicated test circuits. In this regard, a current is made to flow between two ends of a metallic line and the temperature is increased in order to accelerate the electromigration, and any severing of the metallic line is detected.

Such test methods have drawbacks. The increased temperature of the test is not necessarily representative of the temperature distribution within an integrated circuit, and especially within the various tracks of the various metallization levels, during its normal operation. The test temperature may even be higher than the maximum temperature permitted by the transistors, thereby limiting the possible structures.

There is therefore little correlation between faults appearing during the aforementioned tests, as a result of electromigration, and faults that may appear during the use of the integrated circuit.

Thus, a large number of measurements must be carried out when using this method, thereby extending the test period for a given technology.

### SUMMARY

According to one method of implementation and embodiment, it is proposed to improve the reliability with which the risks of a fault appearing, as a result of electromigration, are detected.

According to one aspect, a method of detecting a risk of a fault appearing, in an integrated circuit located on a semiconductor chip, as a result of electromigration, is therefore provided. The method comprises producing at least one resistive test structure, separate from the integrated circuit embedded on said chip, and located on at least one metallization level of the integrated circuit, and detecting said risk of said fault appearing at least during operation of the integrated circuit, and the detection comprises detecting a voltage difference between two points of the resistive test structure.

The test structure is advantageously supplied with electrical power during the operation of the integrated circuit.

A voltage difference may thus be detected directly and automatically within the chip. It is therefore proposed in particular to detect the risks of a fault appearing, as a result of electromigration, during operation of an integrated circuit.

Therefore application of an external power supply across specific terminals is not required to test the resistive structure.

The appearance of a fault within a metallic line of a resistive test structure may lead to an increase in the resistance of this line. The resistance increase may cause the voltage difference.

The test structure is advantageously located close to the integrated circuit and thermally coupled with it. This allows advantage to be taken of the actual operating conditions of the integrated circuit, especially its operating temperature.

Moreover, the resistance properties of the test structure and/or its supply voltage are advantageously chosen so that the current or currents that flow through the test structure are representative of at least some of the currents flowing in the integrated circuit.

Advantageously, the method comprises producing several test structures having different resistance properties, all located on at least one given metallization level of the integrated circuit, and the detection comprises detecting at least one voltage difference between two points of at least one of these resistive test structures.

Because of this, the detection of a risk of a fault appearing may take into consideration differences in the lengths of the lines, which may form one metallization level of the integrated level.

The method may comprise producing several resistive test structures respectively located, at least partially, on several different metallization levels of the integrated circuit, and the detection comprises detecting at least one voltage difference between two points of at least one of these resistive test structures.

Thus, it is possible to detect the risks of a fault appearing in most, even all, of the back end of line (BEOL) interconnect part of the integrated circuit.

The detection of said risk of said fault appearing is furthermore carried out during the testing phases of the circuit, for example before the operating phase.

According to another aspect, a semiconductor device is provided, comprising on a semiconductor chip, an integrated circuit, at least one resistive test structure separate from the integrated circuit and located on at least one metallization level of the integrated circuit, means for supplying the resistive test structure with power, and means for detecting a voltage difference between two points of the resistive test structure.

Advantageously, the resistive test structure comprises an array of metallic lines forming a Wheatstone bridge and the detection means comprise a comparator connected to two points of the Wheatstone bridge.

Several test structures having different resistance properties are at least partially located on several different metallization levels of the integrated circuit.

Furthermore, several resistive test structures are respectively located, at least partially, on several different metallization levels of the integrated circuit.

### BRIEF DESCRIPTION OF THE DRAWINGS

Other advantages and features of the invention will become clear on studying the detailed description of methods of implementation and embodiment, given by way of non-limiting example and illustrated by the appended drawings in which:

FIGS. 1 to 6 illustrate schematically various methods of implementation and embodiment of the invention.

### DETAILED DESCRIPTION OF THE DRAWINGS

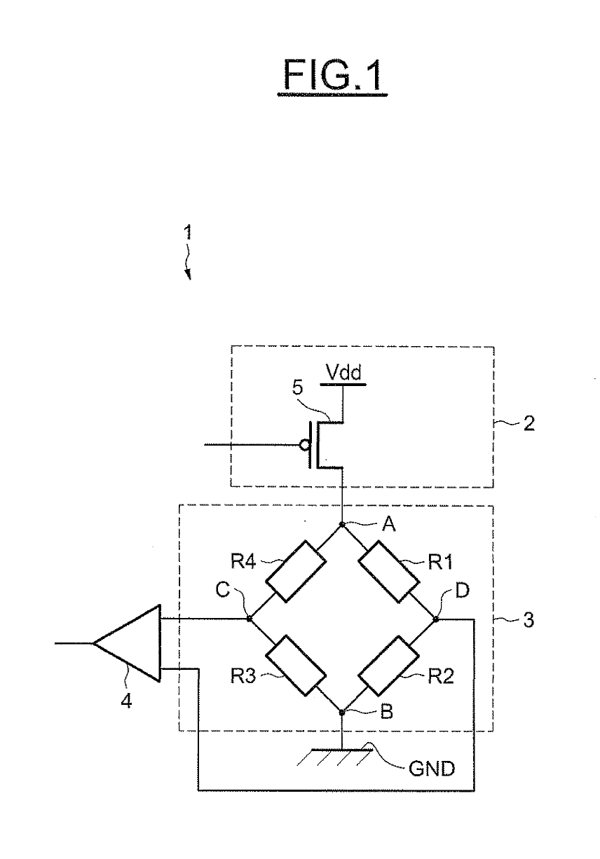

FIG. 1 is a circuit diagram of an embodiment illustrating a test circuit 1 comprising power supply means 2, a resistive test structure 3 and detection means 4 configured to detect a voltage difference between two points of the resistive structure 3.

The resistive structure 3 comprises an array of four resistors R1, R2, R3 and R4 forming a Wheatstone bridge. Two adjacent resistors are separated by a connection point.

The power supply means 2 comprise a pMOS transistor 5 the source of which is connected to a positive DC voltage Vdd (for example 1.8 V). The drain of this transistor is connected, via a first point A, to the resistive structure 3. A second point B, opposite this first point A, is connected to ground GND. The means 4 configured to detect a voltage difference between two points of the structure 3 is connected to two other points C and D.

The means 4 configured to detect a voltage difference may comprise a comparator and an output connected to control means of the integrated circuit.

The pMOS transistor 5 is controlled by control means (not shown) connected to its gate. The pMOS transistor 5, in its on-state, allows a DC current to flow through the resistive test structure 3.

The DC current is advantageously chosen to correspond to the currents flowing through the metallic lines of the integrated circuit.

In this respect, the DC current is adjusted by varying the resistances of resistors R1 to R4 and/or the supply voltage.

The four resistors R1, R2, R3 and R4 of the structure 3 each comprise a set of metallic lines (not shown in this figure). Advantageously, and in a first step, the four resistors R1, R2, R3 and R4 have equal resistances and the voltage measured by the comparator is zero.

The appearance of a fault in at least one of the four resistors R1, R2, R3 or R4 may result in a voltage difference. Since electromigration is a statistical effect it will not affect each of the resistors R1, R2, R3 or R4 in the same way, which would result in a measured voltage of zero.

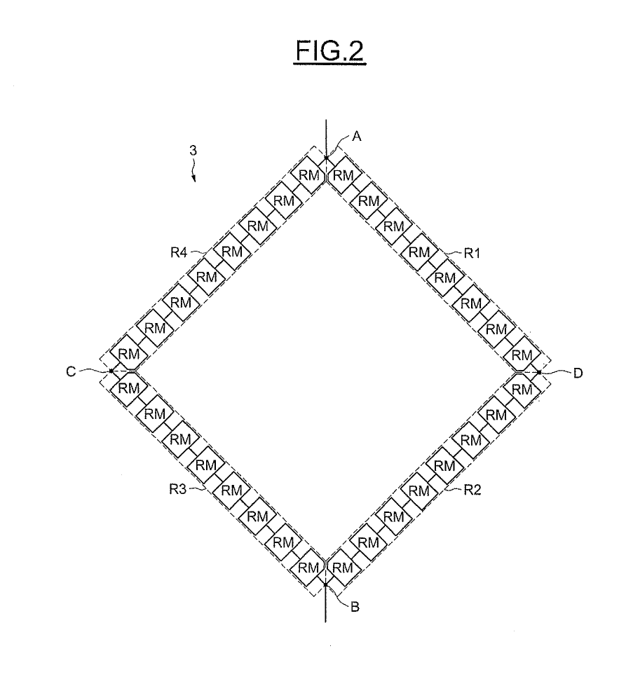

FIG. 2 shows in detail an example of a resistive test structure 3. Each resistor R1, R2, R3 or R4 comprises a set of eight metallic lines RM, shown here as resistors.

The thirty two metallic lines RM will not be affected by electromigration in the same way.

Advantageously, to detect a fault in the metallic lines of the integrated circuit, several resistive structures 3 are used, the metallic lines RM of each resistive structure 3 having different lengths and therefore different resistance properties. For example, the structures 3 may comprise metallic lines RM of length ranging from 8 μm to 250 μm.

The longest metallic lines RM have higher resistances and for a given voltage Vdd (advantageously set to 1.8 V) a lower current density flows through these long lines. Current densities of about 366 mA/μm² flow through the shortest lines whereas current densities of about 12 mA/μm² flow through the longest lines.

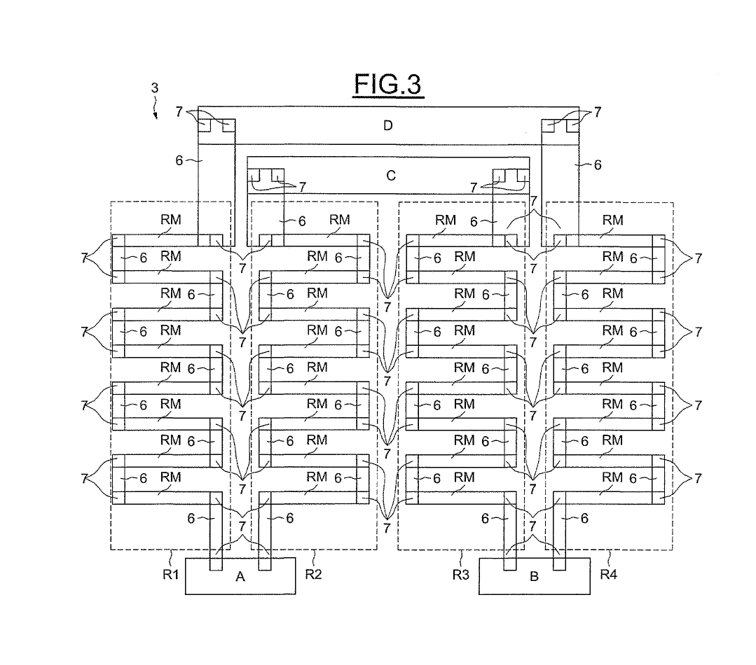

FIG. 3 illustrates, schematically, a top view of an exemplary arrangement of a resistive test structure 3 on a semiconductor chip. The resistive structure 3 comprises metallic lines located on two metallization levels.

This figure shows the resistors R1, R2, R3 and R4 and the resistive metallic lines RM which form them.

The metallic connections corresponding to the points A, B, C and D comprise metallic contacts the resistances of which are negligible relative to the resistances of the metallic lines RM.

The metallic connections of points A, B, C and D belong to the same metallization level of the integrated circuit.

In order to connect the resistors RM to one another and to points A, B, C or D, short metallic lines 6 of a second metallization level are used. The length of the lines 6 is for example about 0.3 μm.

Metallic interconnects 7 (or vias) are used to connect the first metallization level to the second metallization level comprising the short lines 6.

The second metallization level may be a level above that of the first metallization level.

Since the probability of a fault appearing as a result of electromigration is higher within a long line (for example a metallic line RM) than within a short line (for example a short metallic line 6), it is possible to take into consideration only the resistances of the metallic lines RM.

The resistive test structure 3 placed on two metallization levels allows a non-functional, metallic structure to be interposed around the metallic lines RM so as to homogenize the temperature of the resistive test structure 3. This non-functional, metallic structure may comprise dummy lines.

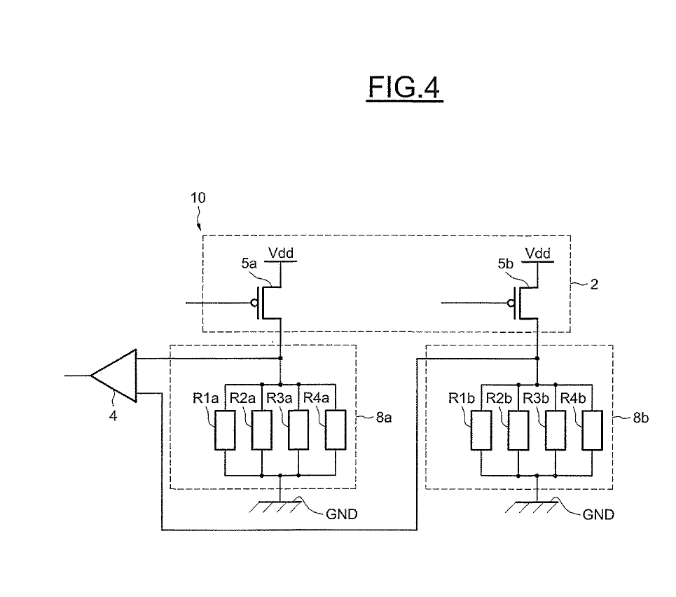

FIG. 4 illustrates another embodiment of a test circuit.

A test circuit 10 makes use of a test structure comprising two identical resistive test units 8a and 8b, each comprising four resistors (R1a, R2a, R3a and R4a, on the one hand, and R1b, R2b, R3b and R4b, on the other hand) connected in parallel.

The units 8a and 8b may comprise metallic lines of different lengths, but the metallic lines are of equal length within a given unit.

Each resistive test unit 8a, 8b is connected via a first point to ground GND and via a second point to the drain of a pMOS transistor 5a or 5b the source of which is connected to a DC voltage source Vdd.

The first point of each resistive test unit 8a, 8b, connected to the drain of a pMOS transistor 5a, 5b, is moreover connected to comparison means 4. The voltage difference across a first terminal of the first unit 8a and a second terminal of the second unit 8b is therefore measured.

Advantageously, when the test circuit 10 is used, the current that flows through the transistor 5a is larger than the current delivered by the transistor 5b.

Thus, the resistors R1a, R2a, R3a and R4a pass a current that is larger than the current flowing through the resistors R1b, R2b, R3b and R4b, the risk of a fault appearing, as a result of electromigration, is therefore higher therein.

The unit 8a therefore ages more rapidly than the unit 8b and the comparator may therefore detect a voltage difference between the two units 8a and 8b of the structure.

Whichever test structure is used, the latter is advantageously located within the chip containing the integrated circuit in which it is desired to detect the risk of faults, related to electromigration, appearing.

It may also be powered for example using the same supply voltage as that of the integrated circuit or using a supply voltage derived from that of the integrated circuit.

The test structure is preferably located close to the integrated circuit so as to be thermally coupled with the latter.

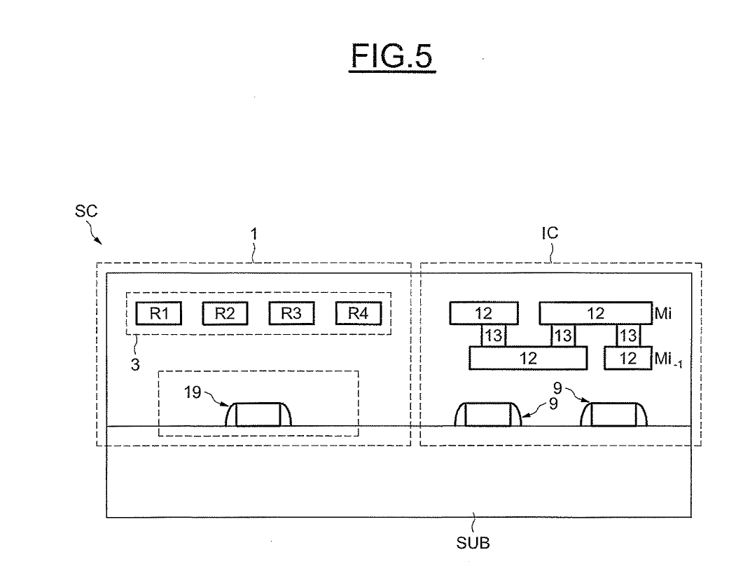

An exemplary embodiment is illustrated in FIG. 5.

FIG. 5 is a view in cross section of a semiconductor chip SC that comprises an integrated circuit IC and, for example, the test circuit 1.

The chip SC comprises a silicon substrate SUB. A certain number of components, for example transistors 9 of the integrated circuit IC, are formed in and on the substrate SUB.

Furthermore, the integrated circuit IC comprises, as is conventional, a BEOL interconnect part between the components. FIG. 5 shows the metallic lines 12 and vertical interconnects 13 of the interconnect part which are located on a metallization level Mi and on a lower metallization level Mi₋₁.

The test circuit 1 comprises a resistive test structure 3 which comprises the four resistors R1, R2, R3 and R4, located here on the metallization level Mi of the integrated circuit IC.

It should be noted that, in the embodiment in FIG. 4, the units 8a and 8b may also be placed on the metallization level Mi.

A number of interconnects and metallic lines, not shown here, allow the structure 3 to be connected to the means 4 of detecting a difference, which may comprise components, such as transistors 19, in the substrate SUB.

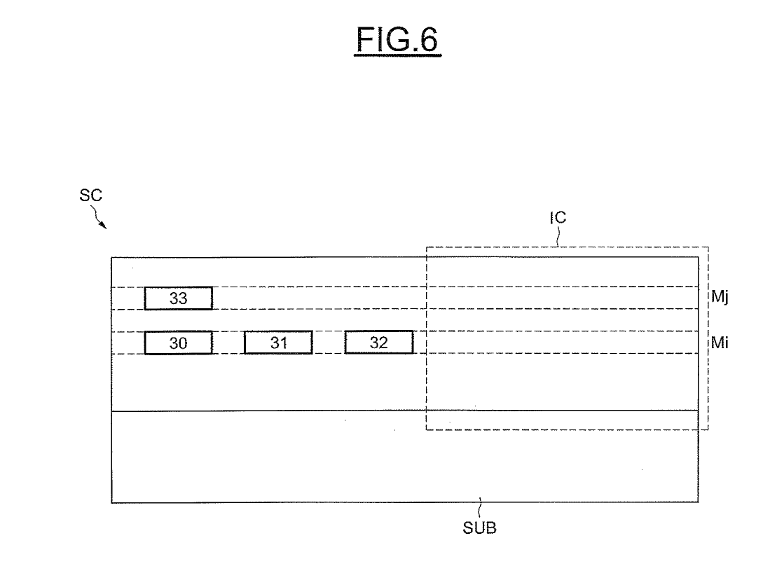

FIG. 6 shows several test structures 30-32 having different resistance properties, possibly placed within the same metallization level Mi. Other, identical or different, test structures (33) may be placed on other metallization levels, for example the level Mj.

Of course, use may also be made of the invention during the test phase of an integrated circuit, in order to reject malfunctioning integrated circuits. Whether all of the resistive test structures are correctly balanced may also be checked in the test period.

Other tests may be implemented, for example Vdd may be varied from 0 V to 1.8 V in order to evaluate Joule-effect losses.

During operation of the integrated circuit the test circuits 1 may also be used periodically, for example with a maximum Vdd of 1.8 V.

What is claimed is:

1. A method of detecting a risk of a fault appearing, in an integrated circuit located on a semiconductor chip, as a result of electromigration, the method comprising:
producing at least one resistive test structure, separated from the integrated circuit embedded on said chip, and located on at least one metallization level of the integrated circuit, and
detecting said risk of said fault appearing at least during operation of the integrated circuit, wherein detecting comprises detecting a voltage difference between two points of the resistive test structure.

2. The method according to claim 1, wherein producing comprises producing several test structures having different resistance properties, all located on at least one given metallization level of the integrated circuit, and wherein detecting comprises detecting at least one voltage difference between two points of at least one of these resistive test structures.

3. The method according to claim 1, wherein producing comprises producing several resistive test structures respectively located, at least partially, on several different metallization levels of the integrated circuit, and wherein detecting comprises detecting at least one voltage difference between two points of at least one of these resistive test structures.

4. The method according to claim 1, wherein detecting said risk of said fault appearing is performed during a testing phase of the integrated circuit.

5. The method according to claim 1, further comprising supplying a current to the at least one resistive test structure which corresponds to an operational current flowing through metal lines of the integrated circuit located on the semiconductor chip.

6. A semiconductor device, comprising:
an integrated circuit formed on a semiconductor chip,
at least one resistive test structure separated from the integrated circuit and located on at least one metallization level of the integrated circuit,
a power supplying circuit configured to supply the resistive test structure with power, and
a detection circuit configured to detect a voltage difference between two points of the resistive test structure.

7. The device according to claim 6, wherein the resistive test structure comprises an array of metallic lines forming a Wheatstone bridge and the detection circuit comprises a comparator having inputs connected to two points of the Wheatstone bridge.

8. The device according to claim 6, wherein the resistive test structure comprises several test structures having different resistance properties that are at least partially located on several different metallization levels of the integrated circuit.

9. The device according to claim 8, in which the several resistive test structures are respectively located, at least partially, on several different metallization levels of the integrated circuit.

10. The device according to claim 6 wherein the power supplying circuit is configured to supply a current to the at least one resistive test structure which corresponds to an operational current flowing through metal lines of the integrated circuit formed on the semiconductor chip.

11. A method, comprising:
producing integrated circuitry for an integrated circuit including metal lines subject to electromigration effects;
producing at least one resistive test structure separated from the integrated circuitry, said resistive test structure comprising at least one metal line;
supplying a current to the at least one resistive test structure which corresponds to an operational current flowing through the metal lines of the integrated circuit; and
detecting a voltage difference with respect to the resistive test structure indicative of an occurrence of an electromigration effect with respect to the metal line of the resistive test structure.

12. The method of claim 11, wherein the resistive test structure comprises a resistive bridge and wherein detecting comprises detecting a voltage imbalance across the resistive bridge.

13. The method of claim 11, wherein producing at least one resistive test structure comprises producing the resistive test structure in a metallization level of the integrated circuit.

14. The method of claim 11, wherein producing at least one resistive test structure comprises producing the resistive test structure in multiple metallization levels of the integrated circuit.

15. A semiconductor device, comprising:
an integrated circuit formed on a semiconductor chip including metal lines subject to electromigration effects,
at least one resistive test structure separated from the integrated circuit and located on at least one metallization level of the integrated circuit, said resistive test structure comprising at least one metal line,
a power supplying circuit configured to supply a current to the at least one resistive test structure which corresponds to an operational current flowing through the metal lines of the integrated circuit, and
a detection circuit configured to detect a voltage difference between two points of the resistive test structure indicative of an occurrence of an electromigration effect with respect to the metal line of the resistive test structure.

16. The device of claim 15, wherein the resistive test structure comprises an array of metallic lines forming a bridge and the detection circuit comprises a comparator having inputs connected to detect an imbalance in the bridge caused by occurrence of an electromigration effect.

17. The device of claim 15, wherein the resistive test structure comprises a plurality of metal lines located on several different metallization levels of the integrated circuit.
